(19) United States
(12) Patent Application Publication
(10) Pub. No.: US 2022/0230984 A1
(43) Pub. Date: Jul. 21, 2022

(54) JOINING MATERIAL FOR BONDING OVERLAPPING COMPONENTS OF POWER ELECTRONIC DEVICES

(71) Applicant: GM GLOBAL TECHNOLOGY OPERATIONS LLC, Detroit, MI (US)

(72) Inventors: Ming Liu, Troy, MI (US); Wenying Yang, Rochester Hills, MI (US)

(73) Assignee: GM GLOBAL TECHNOLOGY OPERATIONS LLC, Detroit, MI (US)

(21) Appl. No.: 17/153,057

(22) Filed: Jan. 20, 2021

(51) Int. Cl. H01L 23/00; B22F 7/06; B22F 3/10

(52) U.S. Cl. CPC H01L 24/29; H01L 2924/15747; B22F 3/1035; H01L 24/83; H01L 2224/29247; H01L 2224/29211; H01L 2224/29209; H01L 2224/29218; H01L 2224/29201; H01L 2224/8384; H01L 2924/01029; H01L 2924/0105; H01L 2924/01049; H01L 2924/0103; H01L 2924/01015; B22F 7/064

(57) ABSTRACT

A joining material for bonding overlapping components of a power electronic device together via a liquid phase sintering process. The joining material includes a mixture of composite particles. Each of the composite particles exhibits a core-shell structure having a core made of a copper-based material and a shell surrounding the core that is made of a low melting point material having a melting temperature or a solidus temperature less than that of the copper-based material of the core. The mixture of composite particles includes a first particulate fraction having a first median particle size and a second particulate fraction having a second median particle size. The first median particle size is at least one order of magnitude larger than the second median particle size.

### INTRODUCTION

The present disclosure relates to electronic devices and, more particularly, to materials and methods of bonding overlapping components of electronic devices.

In an electronic device, multiple active and passive electronic components are interconnected to one another to form an electronic circuit, which is oftentimes mounted on a substrate or die made of semiconductor material. When the electronic components are formed on the same substrate, the resulting device is referred to as an integrated circuit (IC). In practice, such electronic devices are oftentimes assembled into a package that includes multiple interconnected electrically conductive and electrically insulating layers, which may be configured to connect the electronic devices to an external environment and/or to transfer heat away from the electronic devices. In assembly, the electronic devices and the electrically conductive and electrically insulating layers may be mechanically bonded together in the form of a vertical stack using an adhesive or electrically conductive joining material.

Components of electronic packages are oftentimes relatively heat-sensitive. Therefore, during assembly of an electronic package, it is generally desirable to use joining materials that can effectively and efficiently form robust mechanical bonds between such components at relatively low processing temperatures.

### SUMMARY

A joining material for bonding overlapping components of a power electronic device is disclosed. The joining material may comprise a mixture of composite particles. Each of the composite particles may exhibit a core-shell structure including a core and a shell surrounding the core. The core may be made of a copper-based material and the shell may be made of a low melting point material having a melting temperature or a solidus temperature less than that of the copper-based material. The mixture of composite particles may include a first particulate fraction having a first median particle size and a second particulate fraction having a second median particle size. The first median particle size may be at least one order of magnitude larger than the second median particle size.

The copper-based material of the core may comprise, by weight, greater than 96% copper.

The low melting point material of the shell may have a melting temperature or a solidus temperature in a range of 200° C. to 300° C.

The low melting point material of the shell may comprise at least one of tin, indium, zinc, phosphorus, copper(I) phosphide, or an alloy of copper and one or more elemental metals or nonmetals.

The joining material may comprise a binder, dispersant, or solvent. In such case, the mixture of composite particles may constitute, by weight, 70% to 95% of the joining material.

In each composite particle, the core may constitute, by weight, 50% to 90% of the composite particle and the shell may constitute, by weight, 10% to 50% of the composite particle.

The first median particle size may be in a range of 1 micrometer to 30 micrometers, and the second median particle size may be in a range of 10 nanometers to 100 nanometers.

The first particulate fraction may constitute, by volume, 60% to 80% of the mixture of composite particles, and the second particulate fraction may constitute, by volume, 20% to 40% of the mixture of composite particles.

A method of bonding overlapping components of a power electronic device is disclosed. In the method, a volume of joining material may be positioned between opposing surfaces of at least partially overlapping first and second components. The joining material may include a mixture of composite particles, with each of the composite particles exhibiting a core-shell structure that includes a core and a shell surrounding the core. The volume of joining material may be heated at a sintering temperature in a range of 200° C. to 300° C. to form a continuous liquid phase between the first and second components that wets the opposing surfaces of the first and second components. The continuous liquid phase may be allowed to solidify into a solid joint that bonds the first and second components together along their opposing surfaces. The core of each of the composite particles may be made of a copper-based material and the shell of each of the composite particles may be made of a low melting point material having a melting temperature or a solidus temperature less than that of the copper-based material. The mixture of composite particles may include a first particulate fraction having a first median particle size and a second particulate fraction having a second median particle size. The first median particle size may be at least one order of magnitude larger than the second median particle size.

When the volume of joining material is heated at the sintering temperature, at least a portion of the low melting point material of the shells of the composite particles may melt.

The low melting point material of the shells of the composite particles may comprise at least one of tin, indium, zinc, phosphorus, copper(I) phosphide, or an alloy of copper and one or more elemental metals or nonmetals.

When the volume of joining material is heated at the sintering temperature, intermetallic compounds may form within the continuous liquid phase by chemical reaction between the copper-based material of the cores and the low melting point material of the shells of the composite particles. In embodiments, the low melting point material of the shells of the composite particles may comprise tin, and, in such case, the intermetallic compounds may comprise Cu₆Sn₅ and/or Cu₃Sn.

The solid joint formed along the opposing surfaces of the first and second components may exhibit a composite structure including a continuous matrix phase of copper and a particulate phase embedded in the continuous matrix phase. The particulate phase may comprise intermetallic compounds formed within the continuous liquid phase by chemical reaction between the copper-based material of the cores and the low melting point material of the shells of the composite particles.

The volume of joining material may be heated at the sintering temperature by at least one of convection, conduction, radiant heating, resistive heating, electromagnetic induction, or plasma heating.

A protective gas may be applied to the volume of joining material when the volume of joining material is heated at the sintering temperature. In such case, the protective gas may comprise at least one of helium, argon, nitrogen, hydrogen, or carbon monoxide.

A compressive force may not be applied to the volume of joining material during formation of the continuous liquid phase or during formation of the solid joint.

The joining material may include a solvent. In such case, prior to heating the volume of joining material at the sintering temperature, the volume of joining material may be heated to a first temperature in a range of 100° C. to 180° C. to remove at least a portion of the solvent from the joining material.

The first component may comprise a power semiconductor die, and the second component may comprise a thermally and electrically conductive copper substrate.

Another method of bonding overlapping components of a power electronic device is disclosed. In the method, a layer of joining material may be deposited on a substrate. The joining material may include a mixture of composite particles. Each of the composite particles may exhibit a core-shell structure that includes a core and a shell surrounding the core. A component may be positioned in at least partially overlapping relationship with the substrate such that at least a portion of the layer of joining material is sandwiched between a first surface of the substrate and an opposing second surface of the component. The layer of joining material may be heated at a sintering temperature in a range of 200° C. to 300° C. to form a continuous liquid phase between the substrate and the component that wets the opposing first and second surfaces of the substrate and the component. The continuous liquid phase may be allowed to solidify into a solid joint that bonds the component and the substrate together along their opposing first and second surfaces. The core of each of the composite particles may be made of a copper-based material and the shell of each of the composite particles may be made of a low melting point material having a melting temperature or a solidus temperature less than that of the copper-based material. The mixture of composite particles may include a first particulate fraction having a first median particle size and a second particulate fraction having a second median particle size. The first median particle size may be at least one order of magnitude larger than the second median particle size.

The layer of joining material may be deposited on the first surface of the substrate at a thickness in a range of 10 micrometers to 100 micrometers.

The above summary is not intended to represent every possible embodiment or every aspect of the present disclosure. Rather, the foregoing summary is intended to exemplify some of the novel aspects and features disclosed herein. The above features and advantages, and other features and advantages of the present disclosure, will be readily apparent from the following detailed description of representative embodiments and modes for carrying out the present disclosure when taken in connection with the accompanying drawings and the appended claims.

### BRIEF DESCRIPTION OF THE DRAWINGS

Illustrative embodiments will hereinafter be described in conjunction with the appended drawings, wherein like designations denote like elements, and wherein:

FIG. 1 is a schematic side cross-sectional view of a power electronic device including a power semiconductor die mounted on and physically bonded to a stack of interconnected electrically conductive and electrically insulating layers by a thermally and electrically conductive solid joint;

FIG. 2 is a schematic depiction of a cross-section of a mixture of composite particles that may be included in a joining material used to form the thermally and electrically conductive solid joint of FIG. 1;

FIG. 3 is a schematic side cross-sectional view of two overlapping components of a power electronic device, wherein a layer of joining material including the mixture of composite particles of FIG. 2 is sandwiched between opposing surfaces of the components prior to joining; and

FIG. 4 is a schematic side cross-sectional view of the overlapping components of FIG. 3 after the components have been bonded together along their opposing surfaces by formation of a thermally and electrically conductive solid joint therebetween, wherein formation of the solid joint may be accomplished by subjecting the mixture of composite particles in the layer of joining material of FIG. 3 to a liquid phase sintering process.

The present disclosure is susceptible to modifications and alternative forms, with representative embodiments shown by way of example in the drawings and described in detail below. Inventive aspects of this disclosure are not limited to the particular forms disclosed. Rather, the present disclosure is intended to cover modifications, equivalents, combinations, and alternatives falling within the scope of the disclosure as defined by the appended claims.

### DETAILED DESCRIPTION

The presently disclosed joining material includes a mixture of composite particles that allow for the formation of robust, thermally and electrically conductive, solid joints between adjacent, overlapping components of electronic devices at relatively low process temperatures (e.g., less than 300° C.). In addition, the presently disclosed joining material does not include or require the use of relatively expensive metals (e.g., silver) and can be used to form dense solid joints without application of compressive forces at the joining site. Each of the composite particles in the presently disclosed joining material exhibits a core-shell structure defined by a core and a shell that surrounds the core. The core is made of a copper-based material and the shell is made of a material having a relatively low melting temperature and/or solidus temperature, as compared to that of the copper-based material of the core and may be referred to herein as a “low melting point material.” When joining two overlapping components together, a volume of the joining material is placed between opposing surfaces of the components and heated to a sintering temperature, which results in the formation of a continuous liquid phase of molten material that extends between and wets the opposing surfaces of the components to be joined. Thereafter, the continuous liquid phase solidifies into a dense solid joint that bonds the components together along their opposing surfaces.

The mixture of composite particles in the presently disclosed joining material is made up of a first particulate fraction having a first mean particle size and a second particulate fraction having a second mean particle size, with the first mean particle size being several orders of magnitude larger than the second mean particle size. Formulating the joining material with two particulate fractions having significantly different mean particle sizes (as compared to particulate mixtures that are made-up of relatively similarly sized particles without discernable particulate fractions) allows for the formation of relatively dense solid joints in a relatively short amount of time without application of compressive forces at the joining site.

The presently disclosed joining material may be used to mechanically bond and optionally electrically connect a variety of overlapping components of electronic devices together along their opposing surfaces. For example, the presently disclosed joining material may be used to bond overlapping electrically insulating layers and/or electrically conductive layers together and may be used to bond active electronic components (e.g., semiconductor devices, integrated circuits, and/or electromechanical devices) to such layers. In the following description, the presently disclosed joining material is described specifically for use in connection with power electronic devices, but is not limited thereto, as will be appreciated by those of ordinary skill in the art.

The terms “copper-based material” and “copper material,” as used herein, refer to materials that primarily consist of copper (Cu), meaning that copper is the single largest constituent of the material, based upon the overall weight of the material. This may include materials that include, by weight, greater than 50% copper, as well as those that include, by weight, less than 50% copper, so long as copper is the single largest constituent.

As used herein, the term “metal” refers to elemental metals, as well as metal alloys that include a combination of an elemental metal and one or more metal or nonmetal alloying elements.

The terms “melting temperature” or “melting point,” as used herein, refer to the temperature (a point) at which a solid material becomes a liquid at atmospheric pressure. The terms “solidus temperature” or “solidus point,” as used herein, refer to the highest temperature (a point) at which a material is completely solid; at temperatures above the solidus temperature, the material is at least partially liquid.

The term “sintering” refers to a process in which adjacent surfaces of metal-containing solid particles are bonded together by heating. “Liquid phase sintering” refers to a form of sintering in which a liquid phase is formed during heating that coexists with the solid particles.

As used herein, the term “about” means that a number referred to as “about” comprises the recited number plus or minus 1-10% of that recited number.

As used herein, the term “substantially” refers to a great extent or degree, for example, “substantially all” may refer to at least about 90%, at least about 95%, at least about 99%, and more preferably at least 99.9%.

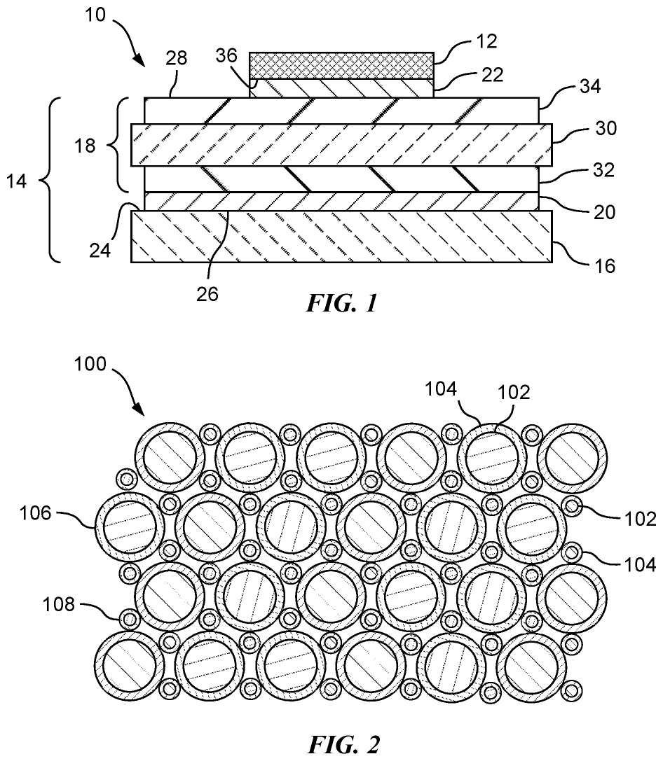

FIG. 1 is a schematic depiction of a power electronic device 10 that includes an active electronic component in the form of a power semiconductor die 12 mounted on a stack 14 of interconnected electrically conductive and electrically insulating layers. The power semiconductor die 12 may be a bipolar transistor, an insulated-gate bipolar transistor (IGBT), a power metal-oxide-semiconductor field-effect transistor (MOSFET), a thyristor, or a diode. The stack 14 of interconnected electrically conductive and electrically insulating layers may be configured to electrically connect the semiconductor die 12 to an external circuit (not shown) and/or to electrically connect or electrically isolate the semiconductor die 12 from one or more additional components of the power electronic device 10. In the embodiment depicted in FIG. 1, the stack 14 of interconnected electrically conductive and electrically insulating layers includes a baseplate 16 and an electrically insulating substrate 18 mounted on and physically attached to the baseplate 16 via formation of a first solid joint 20. The semiconductor die 12 is positioned on top of the stack 14 and is mounted on and physically attached to the substrate 18 via formation of a second solid joint 22.

The baseplate 16 provides mechanical support to the overlying components of the power electronic device 10 and may be coupled to an underlying heatsink (not shown) to help transfer heat away from the power electronic device 10 during operation thereof. The baseplate 16 defines a mounting surface 24 on which the substrate 18 is mounted and may be made of a metal and/or ceramic material that exhibits high thermal conductivity and a low coefficient of thermal expansion.

The electrically insulating substrate 18 mechanically supports the semiconductor die 12 and may electrically isolate the semiconductor die 12 from other electric or electronic components of the power electronic device 10. The substrate 18 has a first major surface 26 that faces toward the baseplate 16 and an opposite second major surface 28 that faces away from the baseplate 16, toward the semiconductor die 12. The substrate 18 is mounted on and physically attached to the mounting surface 24 of the baseplate 16 via the first solid joint 20, with the first solid joint 20 extending in the form of a continuous layer between the mounting surface 24 of the baseplate 16 and the opposing first major surface 26 of the substrate 18. In embodiments, the substrate 18 may exhibit a composite structure in the form of a metallized ceramic substrate including a ceramic intermediate layer 30 sandwiched between and directly bonded to first and second metal layers 32, 34 on opposite first and second sides. In such case, as shown in FIG. 1, the first major surface 26 of the substrate 18 may be defined by the first metal layer 32 disposed on the first side of the ceramic intermediate layer 30, and the second major surface 28 of the substrate 18 may be defined by the second metal layer 34 disposed on the second side of the ceramic intermediate layer 30. The ceramic intermediate layer 30 may be made of a ceramic material, e.g., aluminum-oxide (Al₂O₃), aluminum-nitride (AlN), beryllium oxide (BeO) and/or silicon nitride (Si₃N₄), and the first and second metal layers 32, 34 may be made of copper (Cu), copper oxide (CuO), and/or aluminum (Al). In embodiments, the metallized ceramic substrate may be in the form of a direct bonded copper (DBC) ceramic substrate, a direct bonded aluminum (DBA) ceramic substrate, or an active metal brazing (AMB) ceramic substrate.

The power semiconductor die 12 is mounted on and physically attached to the second major surface 28 of the substrate 18 via the second solid joint 22, with the second solid joint 22 extending in the form of a continuous layer between the second major surface 28 of the substrate 18 and an opposing surface 36 of the semiconductor die 12.

Referring now to FIG. 2, the first and second solid joints 20, 22 are formed between adjacent overlapping components of the power electronic device 10 (i.e., between the baseplate 16 and the substrate 18, and between the substrate 18 and the semiconductor die 12) using a joining material that comprises a mixture of composite particles 100. Each of the composite particles exhibits a core-shell structure including a core 102 and a shell 104 surrounding the core 102.

The core 102 of each of the composite particles is made of a copper-based material and is configured to impart high thermal and electrical conductivity to the resulting solid joints 20, 22. In embodiments, the copper-based material of the core 102 may comprise, by weight, greater than 96% copper, preferably greater than 98% copper, and more preferably greater than 99.9% copper. Pure elemental copper (Cu) has a melting point of about 1084° C. at 1 Atm, a thermal conductivity of about 394 W/m·K at 20° C., and an electrical conductivity in a range of about 100.0% to about 101.5% IACS at 20° C.

The shell 104 of each of the composite particles is formulated to facilitate liquid phase sintering of the mixture of composite particles 100 and may be made of a material having a relatively low melting point and/or a relatively low solidus temperature, as compared to that of the copper-based material of the core 102. As such, the material of the shell 104 may be referred to as a “low melting point material.” For example, the shell 104 may be made of tin (Sn) having a melting point of about 231° C. at 1 Atm, indium (In) having a melting point of about 156° C. at 1 Atm, zinc (Zn) having a melting point of about 419° C. at 1 Atm, phosphorus (P) having a melting point of about 44° C. at 1 Atm, copper(I) phosphide (Cu₃P) having a melting point of about 900° C. at 1 Atm, and/or an alloy of tin (Sn) and/or an alloy of copper (Cu) and one or more elemental metals or nonmetals (e.g., Sn—Cu, Sn—Zn, Sn—Zn—Cu, Sn—Cu—Ag, Sn—In, Sn—Zn—In, Sn—Ag, Sn—In—Ag, Sn—Sb, Sn—Ag—Sb, Sn—Cu—Ni, Sn—Ag—Zn—Cu, and/or Sn—Bi). The melting point and/or the solidus temperature of the material of the shell 104 is preferably less than 300° C. and, more preferably, less than 250° C.

In each composite particle, the core 102 may account for, by weight, 50% to 90% of the composite particle and the shell 104 may account for, by weight, 10% to 50% of the composite particle. The shell 104 of each composite particle may entirely encapsulate the core 102 and may have a thickness overlying the core 102 in a range of one (1) nanometer to one (1) micrometer.

As shown in FIG. 2, the mixture of composite particles 100 includes two particulate fractions: a first particulate fraction 106 having a first median particle size and a second particulate fraction 108 having a second median particle size smaller than the first median particle size of the first particulate fraction 106. In embodiments, the first median particle size of the first particulate fraction 106 may be an order of magnitude larger than the second median particle size of the second particulate fraction 108. For example, the first median particle size of the first particulate fraction 106 may be greater than or equal to ten (10) times and less than or equal to one hundred (100) times greater than the second median particle size of the second particulate fraction 108. The first particulate fraction 106 may constitute, by volume, 60% to 80% or, more preferably, 65% to 75% of the mixture of composite particles 100, and the second particulate fraction 108 may constitute, by volume, 20% to 40% or, more preferably, 25% to 35% of the mixture of composite particles 100. The first particulate fraction 106 may have a first median particle size in a range of 1 micrometer to 30 micrometers and the second particulate fraction 108 may have a second median particle size in a range of 10 nanometers to 100 nanometers.

The first particulate fraction 106 may be substantially free of composite particles with particle diameters of less than 10 nanometers and may be substantially free of composite particles with particle diameters of greater than 10 micrometers. At the same time, the second particulate fraction 108 may be substantially free of composite particles with particle diameters of less than one (1) nanometer and may be substantially free of composite particles with particle diameters of greater than one (1) micrometer. As such, the first particulate fraction 106 may have a first particle size distribution in a range of 10 nanometers to 10 micrometers m and the second particulate fraction 108 may have a second particle size distribution in a range of one (1) nanometer to one (1) micrometer. In some embodiments, the first particle size distribution of the first particulate fraction 106 may partially overlap the second particle size distribution of the second particulate fraction 108. In other embodiments, the first particle size distribution of the first particulate fraction 106 may not overlap the second particle size distribution of the second particulate fraction 108.

The joining material may include one or more additives that may be configured, for example, to facilitate application of the joining material to a surface of one of the components of the power electronic device 10 prior to joining, or to facilitate formation of the joining material into a preformed film or sheet that can be positioned between overlapping components of the power electronic device 10 prior to joining. For example, in addition to the mixture of composite particles 100, the joining material may comprise a binder, a dispersant, and/or a solvent.

In embodiments where the joining material includes one or more additives, the mixture of composite particles 100 may account for, by weight, 70% to 95% of the joining material.

When present, the binder may comprise a polymeric binder and may be present in the joining material in an amount constituting, by weight, 5% to 30% of the joining material. The dispersant may comprise fish oil and may be present in the joining material in an amount constituting, by weight, 1% to 10% of the joining material. The solvent may comprise texanol or terpineol and may be present in the joining material in an amount constituting, by weight, 1% to 10% of the joining material.

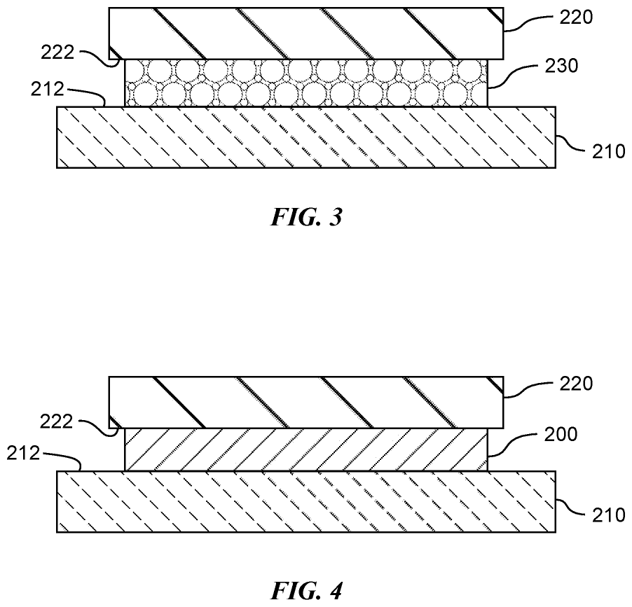

FIGS. 3 and 4 illustrate stages in a method of forming a thermally and electrically conductive joint 200 between overlapping first and second components 210, 220 of a power electronic device. As best shown in FIG. 3, the first and second components 210, 220 to be joined may be positioned in at least partially overlapping spaced-apart relationship, and a volume or layer of joining material 230 may be positioned between opposing first and second surfaces 212, 222 of the first and second components 210, 220. As discussed above, the layer of joining material 230 includes the mixture of composite particles 100 and may include one or more additives. The layer of joining material 230 may be positioned between the first and second components 210, 220 by depositing the layer of joining material 230 on the first surface 212 of the first component 210, for example, using a printing, screen printing, roller coating, extrusion, or spray coating. Alternatively, the layer of joining material 230 may be preformed into the shape of a thin film or sheet of material that is placed on the first surface 212 of the first component 210. The layer of joining material 230 may have a thickness in a range of 10 micrometers to 100 micrometers. The second component 220 is positioned on the first surface 212 of the first component 210 over the layer of joining material 230 such that the layer of joining material 230 is sandwiched between the opposing first and second surfaces 212, 222 of the first and second components 210, 220.

In embodiments where the layer of joining material 230 comprises an additive, the layer of joining material 230 may be preheated at a relatively low temperature in a range of 100° C. to 180° C. to remove at least a portion of the additive therefrom and/or to modify the chemical and/or mechanical properties of the layer of joining material 230 in a manner that is desirable for storage or transport. In some embodiments, the layer of joining material 230 may be preheated after the layer of joining material 230 is positioned on the first surface 212 of the first component 210, but before the second component 220 is positioned on the first surface 212 of the first component 210 over the layer of joining material 230.

After the layer of joining material 230 is positioned between the opposing first and second surfaces 212, 222 of the first and second components 210, 220 and optionally preheated, the layer of joining material 230 may be heated to a sintering temperature to initiate liquid phase sintering of the mixture of composite particles 100 therein. The sintering temperature is a temperature above the solidus temperature of the material of the shell 104 and below the melting temperature of the material of the core 102. As such, the sintering temperature is dependent upon the chemical composition of the shell 104 and the chemical composition of the core 102. The sintering temperature may be a temperature above the melting temperature of the material of the shell 104. The sintering temperature may be a temperature below the solidus temperature of the material of the core 102. The chemical compositions of the core 102 and the shell 104 are formulated to allow for a sintering temperature of less than 300° C. to ensure that the first and second components 210, 220 being joined together remain at a sufficiently low temperature that does not adversely affect the physical integrity of the components 210, 220 during the entire liquid phase sintering process. In embodiments, liquid phase sintering of the mixture of composite particles 100 in the layer of joining material 230 may be performed by heating the layer of joining material 230 to a sintering temperature in a range of 200° C. to 300° C. for a duration in a range of 1-5 minutes.

Without intending to be bound by theory, it is believed that, during the liquid phase sintering process, a continuous liquid phase forms within the layer of joining material 230 that wets the surfaces of the composite particles 100 and also wets the opposing first and second surfaces 212, 222 of the first and second components 210, 220 being joined together. Formation of the continuous liquid phase in the layer of joining material 230 may allow the composite particles 100 to move relative to one another, resulting in consolidation of the composite particles 100 and densification of the layer of joining material 230. During the liquid phase sintering process, the material of the core 102 may react with the material of the shell 104 to form one or more intermetallic phases within the layer of joining material 230. These intermetallic phases may exhibit melting points and/or solidus temperatures above the sintering temperature and may precipitate within the liquid phase as intermetallic particles during the liquid phase sintering process. Solidification of the continuous liquid phase results in the formation of a relatively dense solid joint 200 that bonds the first and second components 210, 220 together along their opposing first and second surfaces 212, 222.

Formation of the relatively high melting point and/or solidus temperature intermetallic phases during the sintering process may result in formation of a solid joint 200 that does not melt or deform when reheated to the same sintering temperature. For example, in embodiments where the material of the core 102 comprises copper and the material of the shell 104 comprises tin, intermetallic phases of Cu₆Sn₅ (m.p. of about 415° C.) and/or Cu₃Sn (m.p. of about 640° C.) may form within the continuous liquid phase during the sintering process. As such, the presently disclosed joining material may allow components of power electronic devices to be joined together at relatively low sintering temperatures (e.g., less than 300° C.) by formation of robust thermally resistant solid joints that can subsequently withstand the relatively high operating temperatures of high power electronic devices (e.g., temperatures of 200° C. or more).

The resulting solid joint 200 may exhibit a composite structure including a continuous matrix phase and one or more particulate phases dispersed throughout and embedded in the matrix phase. The continuous matrix phase may comprise substantially the same material as that of the core 102, i.e., the continuous matrix phase may comprise a copper-based material. The one or more particulate phases may comprise particles of the same material as that of the shell 104 and/or particles of one or more intermetallic compounds formed as a result of chemical reactions between the material of the core 102 and the material of the shell 104 during the sintering process. The resulting solid joint 200 may exhibit a porosity of less than 20% and, more preferably, less than 5%.

The layer of joining material 230 may be heated during the liquid phase sintering process by one or more of the following heating processes: convection, conduction, radiant heating (e.g., infrared and/or laser heating), resistive or Joule heating, electromagnetic induction, and/or plasma heating.

The liquid phase sintering process may be performed in an inert or reducing gas environment, for example, to avoid chemical reactions between the material of the composite particles 100 and the surrounding environment during the sintering process. In such case, a protective gas may be applied to the layer of joining material 230 during the liquid phase sintering process. Examples of protective gases include helium, argon, nitrogen, hydrogen, and/or carbon monoxide.

The presently disclosed joining material may be used to form robust, thermally and electrically conductive, solid joints between adjacent, overlapping components of a variety of high power electronic devices at relatively low processing temperatures. These and other benefits will be readily appreciated by those of ordinary skill in the art in view of the forgoing disclosure.

While some of the best modes and other embodiments have been described in detail, various alternative designs and embodiments exist for practicing the present teachings defined in the appended claims. Those skilled in the art will recognize that modifications may be made to the disclosed embodiments without departing from the scope of the present disclosure. Moreover, the present concepts expressly include combinations and sub-combinations of the described elements and features. The detailed description and the drawings are supportive and descriptive of the present teachings, with the scope of the present teachings defined solely by the claims.

What is claimed is:

1. A joining material for bonding overlapping components of a power electronic device, the joining material comprising:
a mixture of composite particles,
wherein each of the composite particles exhibits a core-shell structure including a core and a shell surrounding the core,
wherein the core is made of a copper-based material and the shell is made of a low melting point material having a melting temperature or a solidus temperature less than that of the copper-based material,
wherein the mixture of composite particles includes a first particulate fraction having a first median particle size and a second particulate fraction having a second median particle size, and
wherein the first median particle size is at least one order of magnitude larger than the second median particle size.

2. The joining material of claim 1 wherein the copper-based material of the core comprises, by weight, greater than 96% copper.

3. The joining material of claim 1 wherein the low melting point material of the shell has a melting temperature or a solidus temperature in a range of 200° C. to 300° C.

4. The joining material of claim 1 wherein the low melting point material of the shell comprises at least one of tin, indium, zinc, phosphorus, copper(I) phosphide, or an alloy of copper and one or more elemental metals or nonmetals.

5. The joining material of claim 1 further comprising: a binder, dispersant, or solvent, and wherein the mixture of composite particles constitutes, by weight, 70% to 95% of the joining material.

6. The joining material of claim 1 wherein, in each composite particle, the core constitutes, by weight, 50% to 90% of the composite particle and the shell constitutes, by weight, 10% to 50% of the composite particle.

7. The joining material of claim 1 wherein the first median particle size is in a range of 1 micrometer to 30 micrometers, and wherein the second median particle size is in a range of 10 nanometers to 100 nanometers.

8. The joining material of claim 1 wherein the first particulate fraction constitutes, by volume, 60% to 80% of the mixture of composite particles, and wherein the second particulate fraction constitutes, by volume, 20% to 40% of the mixture of composite particles.

9. A method of bonding overlapping components of a power electronic device, the method comprising:
positioning a volume of joining material between opposing surfaces of at least partially overlapping first and second components, the joining material including a mixture of composite particles, with each of the composite particles exhibiting a core-shell structure that includes a core and a shell surrounding the core;
heating the volume of joining material at a sintering temperature in a range of 200° C. to 300° C. to form a continuous liquid phase between the first and second components that wets the opposing surfaces of the first and second components; and
allowing the continuous liquid phase to solidify into a solid joint that bonds the first and second components together along their opposing surfaces,
wherein the core of each of the composite particles is made of a copper-based material and the shell of each of the composite particles is made of a low melting point material having a melting temperature or a solidus temperature less than that of the copper-based material,
wherein the mixture of composite particles includes a first particulate fraction having a first median particle size and a second particulate fraction having a second median particle size, and
wherein the first median particle size is at least one order of magnitude larger than the second median particle size.

10. The method of claim 9 wherein heating the volume of joining material at the sintering temperature melts at least a portion of the low melting point material of the shells of the composite particles.

11. The method of claim 9 wherein the low melting point material of the shells of the composite particles comprises at least one of tin, indium, zinc, phosphorus, copper(I) phosphide, or an alloy of copper and one or more elemental metals or nonmetals.

12. The method of claim 9 wherein, during heating of the volume of joining material at the sintering temperature, intermetallic compounds form within the continuous liquid phase by chemical reaction between the copper-based material of the cores and the low melting point material of the shells of the composite particles.

13. The method of claim 12 wherein the low melting point material of the shells of the composite particles comprises tin, and wherein the intermetallic compounds comprise Cu₆Sn₅ and/or Cu₃Sn.

14. The method of claim 9 wherein the solid joint exhibits a composite structure including a continuous matrix phase of copper and a particulate phase embedded in the continuous matrix phase, and wherein the particulate phase comprises intermetallic compounds formed within the continuous liquid phase by chemical reaction between the copper-based material of the cores and the low melting point material of the shells of the composite particles.

15. The method of claim 9 wherein the volume of joining material is heated at the sintering temperature by at least one of convection, conduction, radiant heating, resistive heating, electromagnetic induction, or plasma heating.

16. The method of claim 9 further comprising applying a protective gas to the volume of joining material when the volume of joining material is heated at the sintering temperature, wherein the protective gas comprises at least one of helium, argon, nitrogen, hydrogen, or carbon monoxide.

17. The method of claim 9 wherein a compressive force is not applied to the volume of joining material during formation of the continuous liquid phase or during formation of the solid joint.

18. The method of claim 9 wherein the joining material includes a solvent, and wherein prior to heating the volume of joining material at the sintering temperature, the volume of joining material is heated to a first temperature in a range of 100° C. to 180° C. to remove at least a portion of the solvent from the joining material.

19. The method of claim 9 wherein the first component comprises a power semiconductor die, and wherein the second component comprises a thermally and electrically conductive copper substrate.

20. A method of bonding overlapping components of a power electronic device, the method comprising:
depositing a layer of joining material on a substrate, the joining material including a mixture of composite particles, with each of the composite particles exhibiting a core-shell structure that includes a core and a shell surrounding the core;
positioning a component in at least partially overlapping relationship with the substrate such that at least a portion of the layer of joining material is sandwiched between a first surface of the substrate and an opposing second surface of the component;
heating the layer of joining material at a sintering temperature in a range of 200° C. to 300° C. to form a continuous liquid phase between the substrate and the component that wets the opposing first and second surfaces of the substrate and the component; and
allowing the continuous liquid phase to solidify into a solid joint that bonds the component and the substrate together along their opposing first and second surfaces,
wherein the core of each of the composite particles is made of a copper-based material and the shell of each of the composite particles is made of a low melting point material having a melting temperature or a solidus temperature less than that of the copper-based material,
wherein the mixture of composite particles includes a first particulate fraction having a first median particle size and a second particulate fraction having a second median particle size, and
wherein the first median particle size is at least one order of magnitude larger than the second median particle size.
